(19) United States
(12) Patent Application Publication
(10) Pub. No.: US 2024/0071996 A1
(43) Pub. Date: Feb. 29, 2024

(54) SEMICONDUCTOR PACKAGE AND METHOD OF MANUFACTURING THE SEMICONDUCTOR PACKAGE

(71) Applicant: SAMSUNG ELECTRONICS CO., LTD., Suwon-si (KR)

(72) Inventor: Wonil SEO, Suwon-si (KR)

(21) Appl. No.: 18/216,632

(22) Filed: Jun. 30, 2023

(30) Foreign Application Priority Data
Aug. 24, 2022 (KR) 10-2022-0106110

(51) Int. Cl. H01L 25/065; H01L 23/00; H01L 23/498; H01L 25/00; H10B 80/00

(52) U.S. Cl. CPC H01L 25/0652; H01L 23/49816; H01L 23/49822; H01L 23/49838; H01L 24/16; H01L 24/32; H01L 24/73; H01L 25/50; H10B 80/00; H01L 24/43; H01L 24/48; H01L 2224/16014; H01L 2224/16227; H01L 2224/32145; H01L 2224/4321; H01L 2224/48011; H01L 2224/48227; H01L 2224/73203; H01L 2224/73215; H01L 2224/73253; H01L 2224/73265; H01L 2924/1431; H01L 2924/1434; H01L 2924/15174

(57) ABSTRACT

A semiconductor package includes a redistribution wiring layer having redistribution wirings stacked in at least two levels; a first semiconductor chip arranged on the redistribution wiring layer; a plurality of second semiconductor chips arranged on the first semiconductor chip; first conductive wires electrically connecting first chip pads of the first semiconductor chip and the redistribution wirings of the redistribution wiring layer; second conductive wires electrically connecting second chip pads of the plurality of second semiconductor chips and the redistribution wirings of the redistribution wiring layer; and a sealing unit disposed on the redistribution wiring layer.

### PRIORITY STATEMENT

This application claims priority under 35 U.S.C. § 119 to Korean Patent Application No. 10-2022-0106110, filed on Aug. 24, 2022, in the Korean Intellectual Property Office (KIPO), the disclosure of which is herein incorporated by reference in its entirety.

### TECHNICAL FIELD

The present disclosure relates to a semiconductor package and a method of manufacturing the semiconductor package, and more specifically, to a fan-out semiconductor package and a method of manufacturing the same.

### DESCRIPTION OF THE RELATED ART

In manufacturing a package-on-package (POP), an upper memory package may be stacked on a lower package using copper bumps as the connecting structures. However, this process of stacking the upper memory package using copper bumps on the redistribution wiring layer can be complicated and results in an increase in the thickness of the overall package. Further, when bonding wires are formed after different types of memory chips have been stacked, the size of the package is limited to the size of the memory chip in one level, and the number of input/output terminals is also limited.

### SUMMARY

According to embodiments of the inventive concept, a semiconductor package includes a redistribution wiring layer having redistribution wirings stacked in at least two levels; a first semiconductor chip arranged on the redistribution wiring layer, wherein first chip pads are formed on a front surface of the first semiconductor chip and the front surface of the first semiconductor chip faces the redistribution wiring layer; a plurality of second semiconductor chips arranged on the first semiconductor chip, wherein second chip pads are formed on a front surface of the plurality of second semiconductor chips and the front surface of the plurality of second semiconductor chips faces the redistribution wiring layer, and wherein the second chip pads are exposed from the first semiconductor chip; first conductive wires electrically connecting the first chip pads of the first semiconductor chip and the redistribution wirings of the redistribution wiring layer; second conductive wires electrically connecting the second chip pads of the plurality of second semiconductor chips and the redistribution wirings of the redistribution wiring layer; and a sealing unit disposed on the redistribution wiring layer and covering the first semiconductor chip, the plurality of second semiconductor chips, the first conductive wires, and the second conductive wires.

According to embodiments of the inventive concept, a semiconductor package includes a redistribution wiring layer including, in a plan view, a first region, a second region surrounding the first region, and a third region surrounding the second region, wherein first uppermost redistribution wirings are disposed in the first region and second uppermost redistribution wirings are disposed in the second region; first conductive wires extending upward on the first uppermost redistribution wirings by a first height; second conductive wires extending upward on the second uppermost redistribution wirings by a second height greater than the first height; a first semiconductor chip disposed on the redistribution wiring layer via the first conductive wires; a plurality of second semiconductor chips disposed on the redistribution wiring layer via the second conductive wires, wherein the plurality of second semiconductor chips are arranged on the first semiconductor chip; and a sealing unit on the redistribution wiring layer and covering the first semiconductor chip, the plurality of second semiconductor chips, the first conductive wires, and the second conductive wires.

According to embodiments of the inventive concept, a semiconductor package includes a plurality of second semiconductor chips, each of the plurality of second semiconductor chips having a front surface, wherein second chip pads are formed on the front surface and the plurality of second semiconductor chips are positioned at a same level and spaced apart from each other; a first semiconductor chip arranged on the plurality of second semiconductor chips, wherein the second chip pads are exposed from the first semiconductor chip and first chip pads are formed on a front surface of the first semiconductor chip; first conductive wires extending upwardly on the first chip pads by a first height; second conductive wires extending upwardly on the second chip pads by a second height greater than the first height; a sealing unit covering the plurality of second semiconductor chips, the first semiconductor chip, the first conductive wires, and the second conductive wires and exposing end portions of the first conductive wires and the second conductive wires; and a redistribution wiring layer disposed on the sealing unit, the redistribution wiring layer having redistribution wirings electrically connected to the exposed end portions of the first conductive wires and the second conductive wires respectively.

### BRIEF DESCRIPTION OF THE DRAWINGS

Example embodiments will be more clearly understood from the following detailed description taken in conjunction with the accompanying drawings. FIGS. 1 to 19 represent non-limiting, example embodiments as described herein.

FIG. 1 is a cross-sectional view illustrating a semiconductor package in accordance with example embodiments.

FIG. 2 is a plan view illustrating the semiconductor package in FIG. 1.

FIGS. 3, 4, 5, 6, 7, 8, 9, 10, 11, 12, 13, 14, 15, 16, and 17 are views illustrating a method of manufacturing a semiconductor package in accordance with example embodiments.

FIG. 18 is a plan view illustrating a semiconductor package in accordance with example embodiments.

FIG. 19 is a perspective view illustrating a method of manufacturing a semiconductor package in accordance with example embodiments.

### DETAILED DESCRIPTION OF EXAMPLE EMBODIMENTS

Hereinafter, example embodiments will be explained in detail with reference to the accompanying drawings.

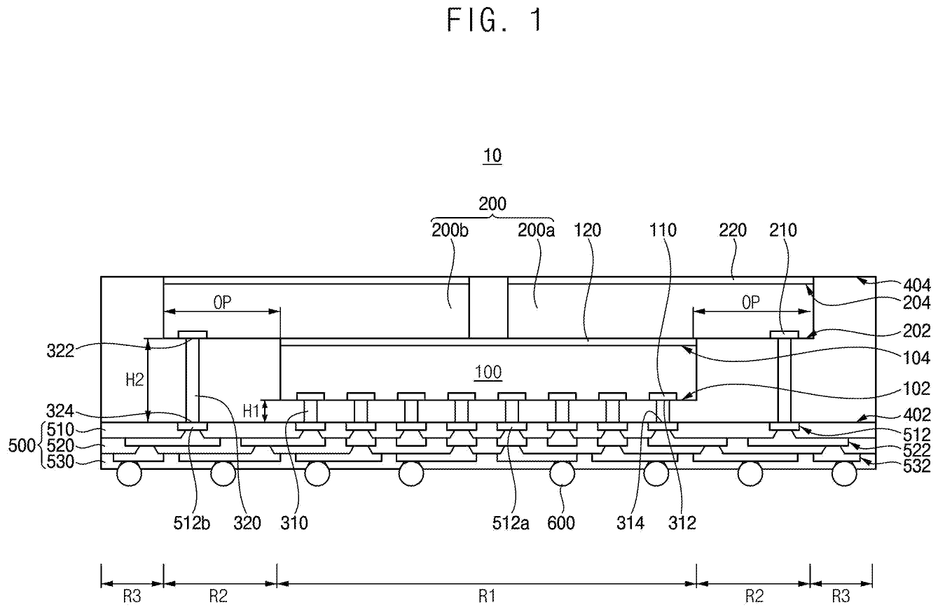

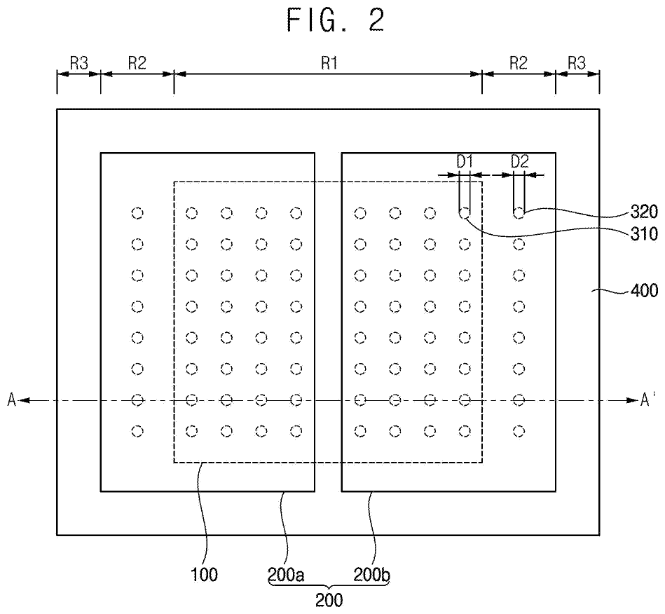

FIG. 1 is a cross-sectional view illustrating a semiconductor package in accordance with example embodiments. FIG. 2 is a plan view illustrating the semiconductor package in FIG. 1. FIG. 1 is a cross-sectional view taken along line A-A in FIG. 2.

Referring to FIGS. 1 and 2, a semiconductor package 10 may include a first semiconductor chip 200, a plurality of second semiconductor chips 200, first and second vertical conductive structures 310 and 320, a sealing unit 400, and a redistribution wiring layer 500. Additionally, the semiconductor package 10 may further include outer connection units 600.

In addition, the semiconductor package 10 may be a multi-chip package (MCP) including multiple different kinds of semiconductor chips. The semiconductor package 10 may be a System In Package (SIP) including a plurality of semiconductor chips stacked or arranged in one package to perform all or most of the functions of an electronic system.

In example embodiments, the redistribution wiring layer 500 may include redistribution wirings 512, 522, and 532. In some examples, the redistribution wiring layer 500 includes multiple levels of redistribution wirings. In some examples, there are at least two layers of redistribution wirings in the redistribution wiring layer 500. In some examples, the redistribution wiring layer 500 includes redistribution wirings 512, 522 and 532, which are positioned on at least two levels. The first semiconductor chip 100 and the plurality of second semiconductor chips 200 may be arranged on the redistribution wiring layer 500 and may be electrically connected to the redistribution wirings 512, 522, and 532. Accordingly, the redistribution wiring layer 500 may serve as a redistribution wiring layer of a fan-out package. A fan-out package is a type of semiconductor package design in which the interconnects are distributed across a larger area to increase the number of input/output (I/O) terminals. In traditional semiconductor packages, the interconnects are limited to a small area and the number of I/O terminals is limited as a result. According to some embodiments, by using the fan-out semiconductor package, the interconnects may be spread out from the central die to the peripheral area of the package, allowing for a larger number of I/O terminals to be included. According to some embodiments, a fan-out region may be formed by using the fan-out semiconductor package.

In some examples, the redistribution wiring layer 500 may include first, second, and third insulation layers 510, 520, and 530 sequentially stacked on one another, and first to third redistribution wires 512, 522, and 532 disposed in the first, second, and third insulation layers 510, 520 and 530 respectively. The first redistribution wirings 512 may be uppermost redistribution wirings among the redistribution wirings of the redistribution wiring layer 500. As will be described later, the first redistribution wirings 512 may include first uppermost redistribution wirings 512a electrically connected to the first semiconductor chip 100 and second uppermost redistribution wirings 512b electrically connected to the plurality of second semiconductor chips 200.

For example, the first to third insulation layers may include a polymer, a dielectric layer, etc. The first to third redistribution wirings may include copper (Cu), aluminum (Al), tin (Sn), nickel (Ni), gold (Au), platinum (Pt), or an alloy thereof.

In a plan view, the redistribution wiring layer 500 may include a first region R1 overlapping the first semiconductor chip 100, a second region R2 surrounding the first region R1 and a third region R3 surrounding the second region R2. The second region R2 and the first region R1 inside the second region R1 may overlap the plurality of second semiconductor chips 200. The third region R3 may be a fan-out region outside the region where the first and second semiconductor chips are disposed, and second uppermost redistribution wirings 512b may be arranged in the second region R2. In some examples, a fan-out region may be formed by distributing the external connection units from the semiconductor chips to the outer edges of the package. In some examples, in the third region R3, the external connection units are redirected from the semiconductor chips to the outer edges of the package using redistribution wiring layers and conductive wires.

In example embodiments, the first semiconductor chip 100 may be disposed on the redistribution wiring layer 500 via the first vertical conductive structures 310, and the plurality of second semiconductor chips 200 may be disposed on the redistribution wiring layer 500 via the second vertical conductive structures 320.

The first semiconductor chip 100 may be arranged in the first region R1 of the redistribution wiring layer 500. The first semiconductor chip 100 may be arranged such that a front surface 102, i.e., active surface on which first chip pads 110 are formed faces the redistribution wiring layer 500. In a plan view, the first semiconductor chip 100 may have a quadrangular shape having four sides. The first chip pads 110 may be arranged in an array form on the entire front surface 102 of the first semiconductor chip 100.

The first semiconductor chip 100 may be a logic chip including an integrated circuit. For example, the first semiconductor chip 100 may a controller for controlling memory chips. The first semiconductor chip may be a processor chip such as ASIC for host such as CPU, GPU, SOC, etc. For example, a thickness of the first semiconductor chip 100 may be within a range of 400 μm to 500 μm.

The plurality of second semiconductor chips 200 may be spaced apart from each other on the first semiconductor chip 100. Two second semiconductor chips 200a and 200b of the plurality of second semiconductor chips 200 may be disposed at the same level on the first semiconductor chip 100. In some examples, the two second semiconductor chips 200a and 200b may be stacked in one level on the first semiconductor chip 100. Backside surfaces 204 of the second semiconductor chips 200a and 200b may have the same heights from the backside surface 104 of the first semiconductor chip 100 or an upper surface of the redistribution wiring layer 500.

The second semiconductor chips 200a and 200b may be arranged such that a second front surface 202, i.e., active surface on which second chip pads 210 are formed faces the redistribution wiring layer 500. Each of the second semiconductor chips 200a and 200b may have a quadrangular shape having four sides in a plan view. The second chip pads 210 may be disposed in a peripheral region along one side surface of each of the second semiconductor chips 200a and 200b. The peripheral regions of the second semiconductor chips 200a and 200b in which the second chip pads 210 are arranged may face in opposite directions.

The second semiconductor chip may be a memory chip including a memory circuit. For example, the second semiconductor chip may include a volatile memory device such as SRAM and DRAM, and a non-volatile memory device such as a flash memory device, PRAM, MRAM, RRAM, etc.

In example embodiments, the second semiconductor chips 200 may be arranged such that the second chip pads 210 of each of the second semiconductor chips 200 are exposed by the first semiconductor chip 100. The peripheral regions of the second semiconductor chips 200a and 200b along which the second chip pads 210 are disposed may be exposed by the first semiconductor chip 100. In some examples, the second chip pads 210 are positioned in a way that they are not covered or obstructed by the first semiconductor chip 1M. In some cases, the second chip pads 210 are accessible and visible from the front surface of the first semiconductor chip 100. In some examples, the front surfaces of the plurality of second semiconductor chips 200, where the second chip pads 210 are disposed, are positioned in a way that the second chip pads 210 are not hidden or covered by the first semiconductor chip 100 and are accessible and visible from the front surface of the first semiconductor chip 100. Accordingly, each of the second semiconductor chips 200a and 200b may include an overhang portion OP that protrudes from one side of the first semiconductor chip 100, and the second chip pads 210 may be disposed on a lower surface of the overhang portion OP. In some examples, the overhang portion OP is a portion of the second semiconductor chips 200 that extends beyond an edge of the first semiconductor chip 100 on a side. In some examples, the second semiconductor chips 200a and 200b are positioned in such a way that a portion of the second semiconductor chips 200a and 200b extends beyond an edge of the first semiconductor chip 100 and forms the overhang portion OP of the second semiconductor chips 200a and 200b that is not in direct contact with the first semiconductor chip 100.

A first adhesive film 120 may be attached to the backside surface 104 of the first semiconductor chip 100, and second adhesive films 220 may be attached to the backside surfaces 204 of the plurality of second semiconductor chips 200. The first semiconductor chip 100 may be attached to the front surfaces of the plurality of second semiconductor chips 200 using the first adhesive films 120. The first and second adhesive films 120 and 220 may include an adhesive film such as a die attach film (DAF). In some cases, the second adhesive films 220 may be omitted, and the backside surfaces 204 of the plurality of second semiconductor chips 200 may be exposed from the sealing unit 400. In these cases, the backside surfaces 204 are positioned in a way that they are not covered or obstructed by the sealing unit 400. In some examples, the backside surfaces 204 are accessible and visible from the sealing unit 400. In some examples, the front surfaces of the plurality of second semiconductor chips 200, on which the backside surfaces 204 are disposed, are positioned in a way that the backside surfaces 204 are not hidden or covered by the sealing unit 400 and are accessible and visible from the sealing unit 400.

The number, size, arrangement, etc. of the first and second semiconductor chips are provided as examples, and the present disclosure might not be necessarily limited thereto. In addition, although only a few first and second chip pads are illustrated in the drawings, the structures, shapes, and arrangements of the first and second chip pads are provided as examples, and the present disclosure might not be necessarily limited thereto.

In example embodiments, the first vertical conductive structures 310 may electrically connect the first chip pads 110 of the first semiconductor chip 100 and the redistribution wirings 512b of the redistribution wiring layer 500. The second vertical conductive structure 320 may electrically connect the second chip pads 210 of the plurality of second semiconductor chips 200 and the redistribution wirings 512a of the redistribution wiring layer 500.

For example, the first vertical conductive structure 310 may include a first conductive wire that extends from the first uppermost redistribution wiring 512a of the redistribution wiring layer 500 to the first chip pad 110 of the first semiconductor chip 100. The second vertical conductive structure 320 may include a second conductive wire that extends from the second uppermost redistribution wiring 512b of the redistribution wiring layer 500 to the second chip pad 210 of the second semiconductor chip 200. The first and second conductive wires may be formed by a bonding wire process.

The first vertical conductive structure 310 may include a first end portion 312 bonded to the first chip pad 110 of the first semiconductor chip 100 and a second end portion 314 bonded to the first uppermost redistribution wiring 512a of the redistribution wiring layer 500. The second vertical conductive structure 320 may include a first end portion 322 bonded to the second chip pad 210 of the second semiconductor chip 200 and a second end portion 324 bonded to the second uppermost redistribution wiring 512b of the redistribution wiring layer 500.

The first vertical conductive structure 310 may have a first height H1 from the redistribution wiring layer 500, and the second vertical conductive structure 320 may have a second height H2 greater than the first height H1 from the redistribution wiring layer 500. The first height H1 may be within a range of 10 μm to 50 μm, and the second height H2 may be within a range of 400 μm to 550 μm. The first vertical conductive structure 310 may have a first diameter D1, and the second vertical conductive structure 320 may have a second diameter D2. The second diameter D2 may be greater than or equal to the first diameter D1. The first and second diameters may be within a range of 15 μm to 25 μm.

In example embodiments, the sealing unit 400 may be disposed on the redistribution wiring layer 500 to cover the first semiconductor chip 100, the plurality of second semiconductor chips 200, and the first and second vertical conductive structures 310 and 320. The sealing unit may include an epoxy molding compound (EMC).

The sealing unit 400 may have a first surface 402 facing the redistribution wiring layer 500 and a second surface 404 opposite to the first surface 402. The first end portions 312 and 322 of the first and second vertical conductive structures 310 and 320 may be exposed from the first surface 402 of the sealing unit 400. In some examples, the first end portions 312 and 322 of the first and second vertical conductive structures 310 and 320 are positioned in a way that they are not covered or obstructed by the first surface 402 of the sealing unit 400. The second adhesive films 220 attached to the backside surfaces 204 of the second semiconductor chips 200 may be exposed from the second surface 404 of the sealing unit 400. In some examples, the second adhesive films 220 are positioned in a way that they are not covered or obstructed by the first surface 402 of the sealing unit 400.

The redistribution wiring layer 500 may include the third insulation layer 530 disposed on the second insulation layer 520 to expose portions of the third redistribution wirings 532. The third insulating layer 530 may serve as a passivation layer. A bump pad such as an under bump metallurgy (UBM) may be disposed on the third redistribution wiring 532 exposed by the third insulation layer 530. An UBM may be a metal structure placed between the bump and the substrate in flip-chip packaging. The UBM layer may be an interconnect between the bump and the substrate and may provide a surface for the bump to make a reliable electrical and mechanical connection. In this case, the exposed portion of the third redistribution wiring 532 may serve as a landing pad or a package pad.

In example embodiments, the external connection units 600 for electrical connection with an external device may be disposed on the package pads on an outer surface of the redistribution wiring layer 500. For example, an external connection unit 600 may be a solder ball. The semiconductor package 10 may be disposed on a module substrate via the solder balls.

Some of the external connection units 600 may be disposed in the third region R3 outside the region where the first and second semiconductor chips are disposed. Accordingly, the semiconductor package 10 may be provided as a fan-out package.

As mentioned above, the semiconductor package 10 may include the redistribution wiring layer 500 having the first region R1, the second region R2 surrounding the first region R1 and the third region R3 surrounding the second region R2 and including the first uppermost redistribution wirings 512a arranged in the first region R1 and the second uppermost redistribution wirings 512b arranged in the second region R2, the first conductive wires 310 extending upward on the first uppermost redistribution wirings 512a by the first height H1, the second conductive wires 310 extending upward on the second uppermost redistribution wirings 512b by the second height H2 greater than the first height H1, the first semiconductor chip 100 disposed on the redistribution wiring layer 500 via the first conductive wires 320, the plurality of second semiconductor chips 200 disposed on the redistribution wiring layer via the second conductive wires 320 and arranged on the first semiconductor chip 100, and the sealing unit 400 on the redistribution wiring layer 500 to cover the first semiconductor chip 100, the plurality of second semiconductor chips 200 and the first and second conductive wires 310 and 320.

The plurality of second semiconductor chips 200 may be disposed at the same level on the first semiconductor chip 100. The first semiconductor chips 100 and the plurality of second semiconductor chips 200 different from each other may be configured in one package by using the first and second conductive wires 310 and 320 as vertical conductive structures.

Accordingly, by using the first and second conductive wires, the overall thickness of the package may be reduced, the inductance of the signal path may be greatly reduced, and the number of input/output terminals may be increased with the fan-out structure.

Hereinafter, a method of manufacturing the semiconductor package in FIG. 1 will be explained.

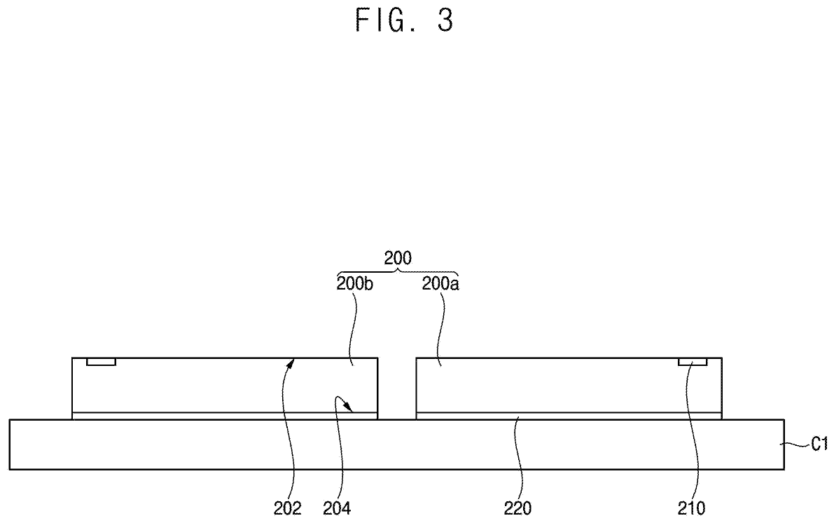

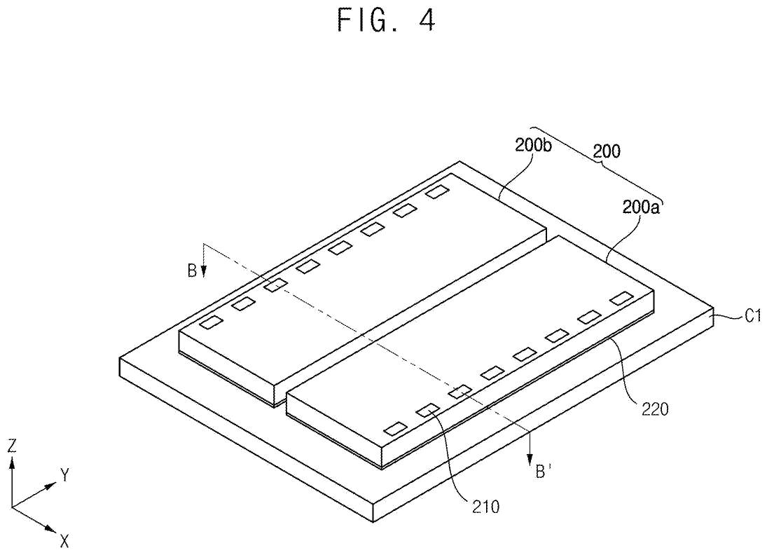

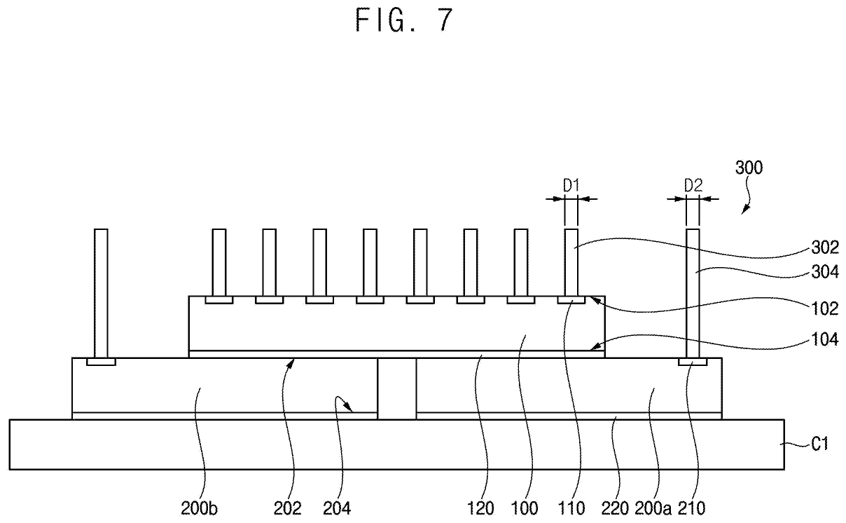

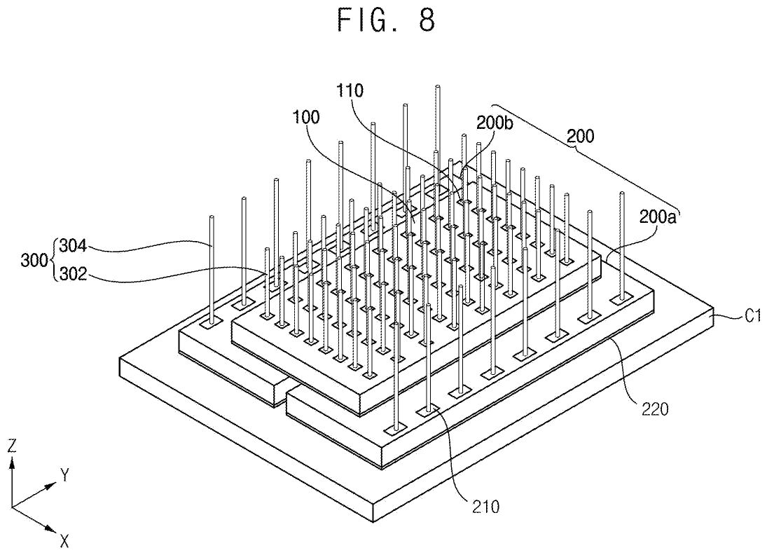

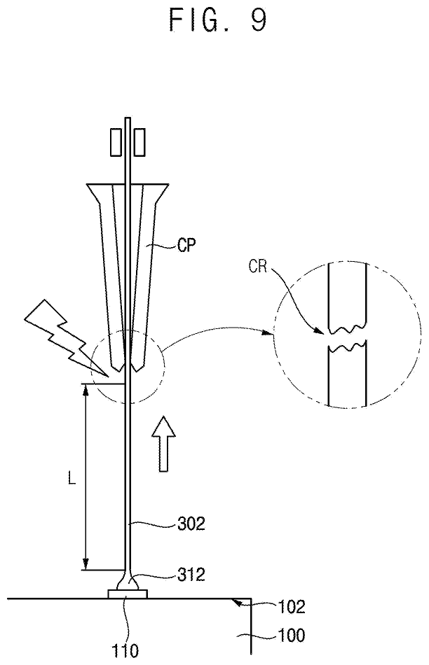

FIGS. 3, 4, 5, 6, 7, 8, 9, 10, 11, 12, 13, 14, 15, 16, and 17 are views illustrating a method of manufacturing a semiconductor package in accordance with example embodiments. FIGS. 3, 5, 7, 10, 12, 14, and 16 are cross-sectional views illustrating a method of manufacturing a semiconductor package in accordance with example embodiments. FIGS. 4, 6, 8, 11, 13, 15 and 17 are perspective views corresponding to FIGS. 3, 5, 7, 10, 12, 14 and 16, respectively. FIG. 9 is a cross-sectional view illustrating a process of forming vertical wires in FIG. 7. FIG. 3 is a cross-sectional view taken along line B-B′ in FIG. 4.

Referring to FIGS. 3 and 4, a plurality of second semiconductor chips 200 may be arranged on a carrier substrate C1.

In example embodiments, two second semiconductor chips 200a and 200b may be arranged on the carrier substrate C1 and are spaced apart from each other. In some examples, front surfaces of the second semiconductor chips 200a and 200b are on the same horizontal plane and are not stacked on top of each other. In some examples, the second semiconductor chips 200a and 200b are positioned side by side on the carrier substrate C1, with a space between each other. The carrier substrate C1 may include a glass substrate, a silicon substrate, a ceramic substrate, etc. For example, the carrier substrate C1 may be a wafer, and a plurality of semiconductor packages may be simultaneously manufactured on the carrier substrate C1.

The second semiconductor chips 200a and 200b may be attached to an upper surface of the carrier substrate C1 using second adhesive films 220. The second semiconductor chips 200a and 200b may be attached to the carrier substrate C1 by using the adhesive film such as a die attach film (DAF) by a die attach process.

The second semiconductor chips 200a and 200b may be arranged such that a backside surface 204, i.e., non-active surface opposite to a second front surface 202 on which second chip pads 210 are formed faces the carrier substrate C1. Each of the second semiconductor chips 200a and 200b may have a quadrangular shape having four sides in a plan view. The second chip pads 210 may be disposed in a peripheral region along one side surface of each of the second semiconductor chips 200a and 200b. The peripheral regions of the second semiconductor chips 200a and 200b in which the second chip pads 210 are arranged may face in opposite directions.

The second semiconductor chips 200a and 200b may be arranged at the same level on the carrier substrate C1. In some examples, the second semiconductor chips 200a and 200b may be stacked in one level on the carrier substrate C1. Upper surfaces of the second semiconductor chips 200a and 200b may have the same height from the upper surface of the carrier substrate C1. As will be described later, the plurality of second semiconductor chips 200a and 200b are arranged in one level on the carrier substrate C1, thereby providing a thin fan-out package.

The second semiconductor chip may be a memory chip including a memory circuit. For example, the second semiconductor chip may include a volatile memory device such as SRAM and DRAM, and a non-volatile memory device such as a flash memory device, PRAM, MRAM, RRAM, etc.

The number, sizes, arrangements, etc. of the second semiconductor chips are provided as examples, and it will be understood that it may not be limited thereto. Also, although only a few second chip pads are illustrated in the drawings, the structures, shapes, arrangements, etc. of the second chip pads are provided as examples, and it will be understood that it may not be limited thereto.

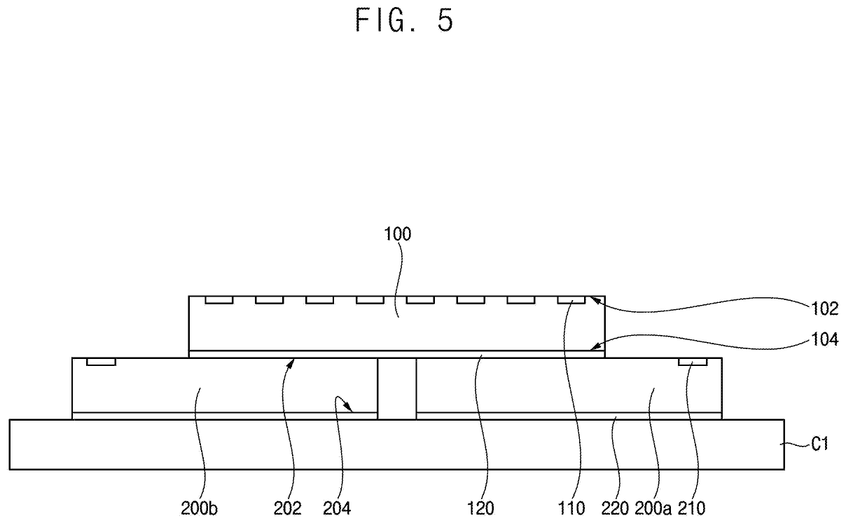

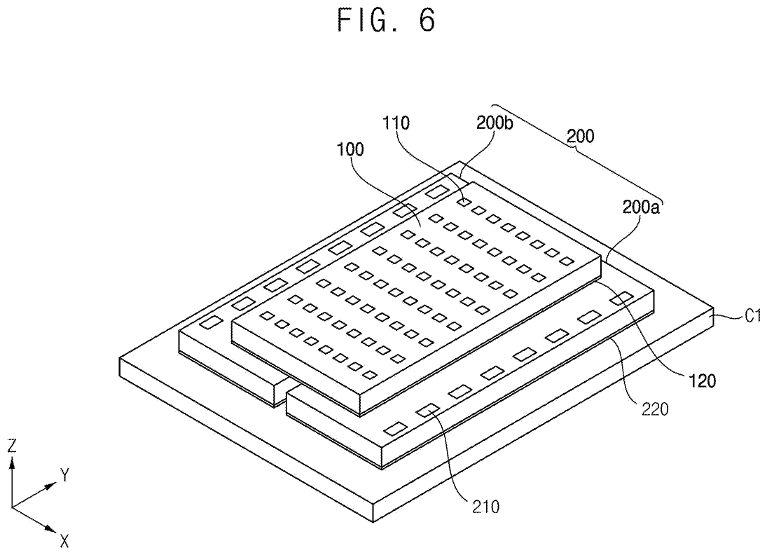

Referring to FIGS. 5 and 6, at least one first semiconductor chip 100 may be disposed on the plurality of second semiconductor chips 200. The first semiconductor chip 100 may be arranged on the plurality of second semiconductor chips 200 such that the second chip pads 210 of the second semiconductor chips 200 are exposed by the first semiconductor chip 100. In a plan view, the first semiconductor chip 100 may be arranged in a rectangular support region provided by the plurality of second semiconductor chips 200. Accordingly, the peripheral regions of the second semiconductor chips 200a and 200b on which the second chip pads 210 are formed may be exposed by the first semiconductor chip 100.

The first semiconductor chip 100 may be attached to upper surfaces of the plurality of second semiconductor chips 200a and 200b using a first adhesive film 120. The first semiconductor chip 100 may be attached on the plurality of second semiconductor chips 200a and 200b by using an adhesive film such as a die attach film (DAF) through a die attach process.

The first semiconductor chip 100 may be arranged such that a backside surface 104, i.e., non-active surface opposite to a front surface 102 on which first chip pads 110 are formed, that is, faces the carrier substrate C1. In a plan view, the first semiconductor chip 100 may have a quadrangular shape having four sides. The first chip pads 110 may be arranged in an array form on the entire front surface 102 of the first semiconductor chip 100.

The first semiconductor chip 100 may be a logic chip including an integrated circuit. For example, the first semiconductor chip 100 may a controller for controlling memory chips. The first semiconductor chip may be a processor chip such as ASIC for host such as CPU, GPU, SOC, etc.

Referring to FIGS. 7 to 9, a plurality of preliminary vertical conductive structures 300 may be formed on the plurality of second semiconductor chips 200a and 200b and the first semiconductor chip 100. First preliminary vertical conductive structures 302 may be formed on the first chip pads 110 of the first semiconductor chip 100 respectively, and second preliminary vertical conductive structures 304 may be formed on the second chip pads 210 of the plurality of second semiconductor chips 200a and 200b respectively.

In example embodiments, the preliminary vertical conductive structures 300 may be formed by a bonding wire process. The first and second preliminary vertical conductive structures 302 and 304 may be bonding wires formed by the bonding wire process.

As illustrated in FIG. 9, after one end portion of a wire drawn from a capillary CP is bonded to the first chip pad 110 of the first semiconductor chip 100, the capillary CP may move in a vertical direction to withdraw the wire. Then, when the wire is extended by a predetermined length (L), a portion (CR) of the wire may be cut to form the first preliminary conductive wire 302. Accordingly, the first preliminary conductive wire 302 may have a first end portion 312 that is bonded to the first chip pad 110. Similarly, the second preliminary conductive wire 304 may have a first end portion that is bonded to the second chip pad 210.

For example, the first and second preliminary vertical conductive structures 302 and 304 may be formed to have the same heights from the upper surface of the carrier substrate C1. The first preliminary vertical conductive structure 302 may have a first diameter D1, and the second preliminary vertical conductive structure 304 may have a second diameter D2. The second diameter D2 may be greater than or equal to the first diameter D1. The first and second diameters may be within a range of 15 μm to 25 μm.

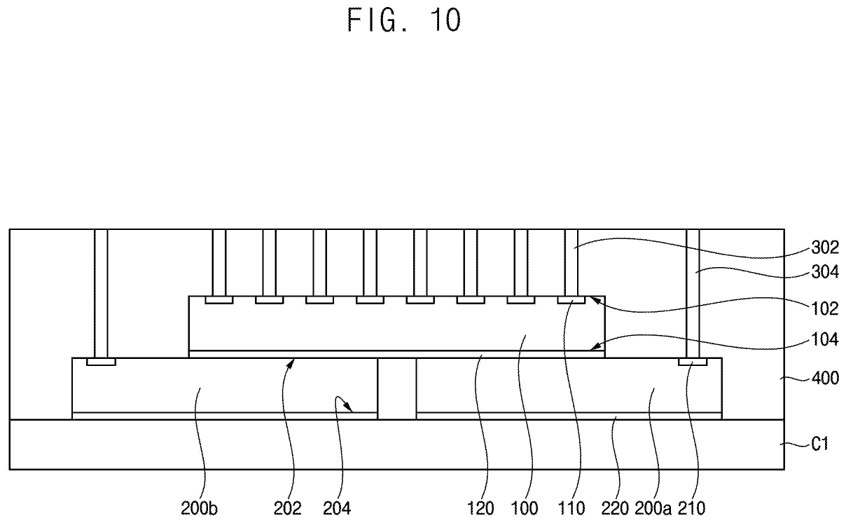

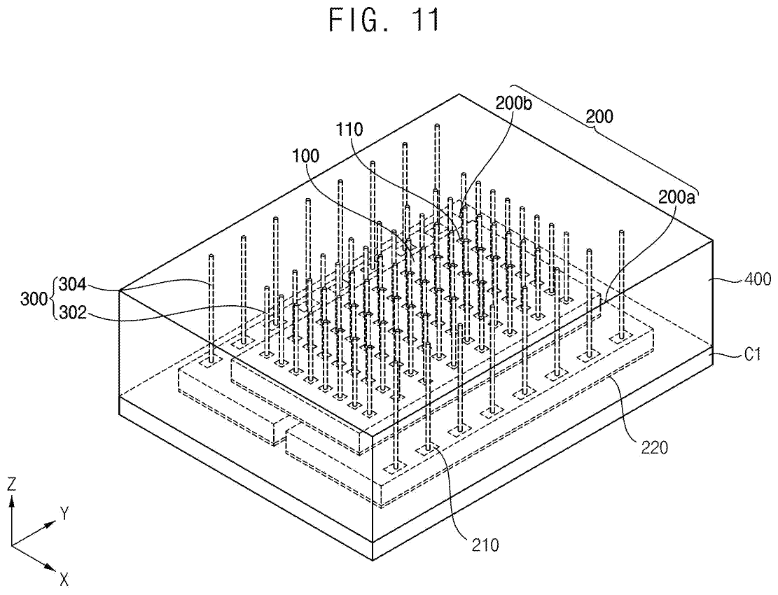

Referring to FIGS. 10 and 11, a sealing unit 400 may be formed on the upper surface of the carrier substrate C1 to cover the plurality of second semiconductor chips 200, the first semiconductor chip 100 and the preliminary vertical conductive structures 300.

The sealing unit 400 may be formed to completely cover or expose second end portions opposite to the first end portions of the preliminary vertical conductive structures 300. The sealing unit 400 may include a thermosetting resin, for example, an epoxy mold compound (EMC).

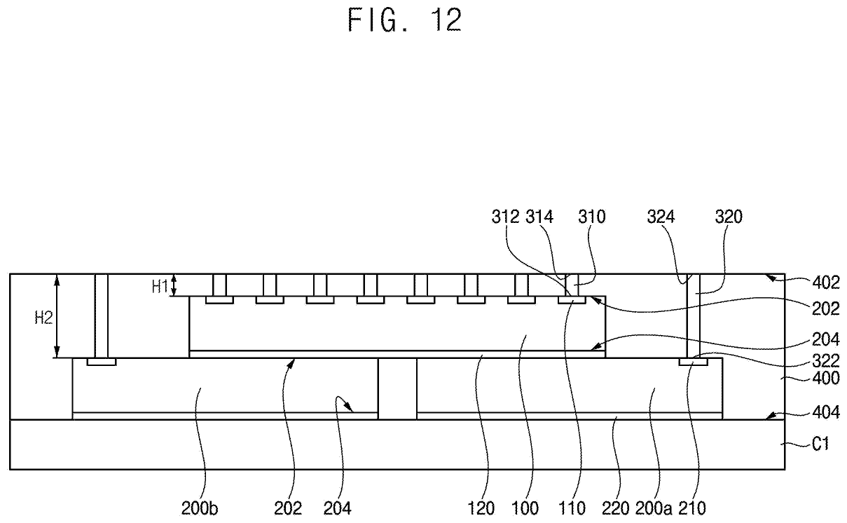

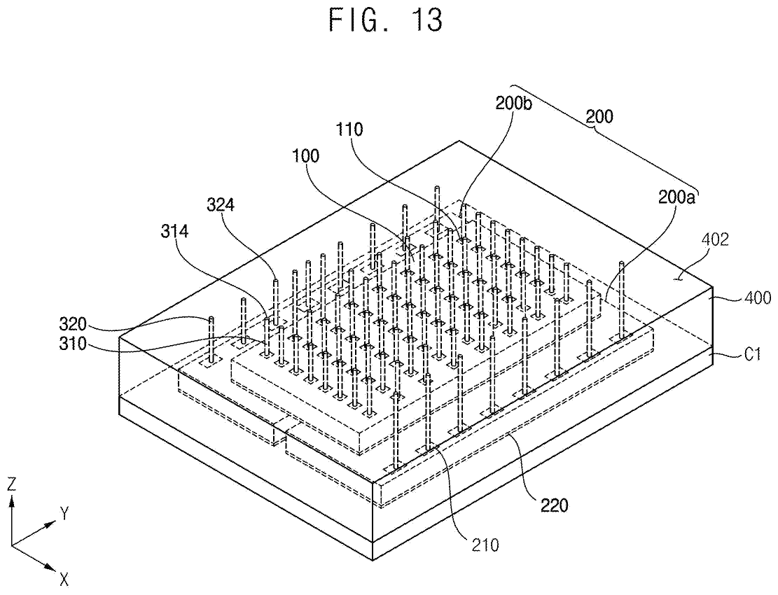

Referring to FIGS. 12 and 13, an upper surface of the sealing unit 400 may be ground to have a desired thickness. At this time, the preliminary vertical conductive structures 300 may also be partially removed to form first and second vertical conductive structures 310 and 320 having desired heights. For example, the upper surface of the sealing unit 400 may be removed by a mechanical chemical polishing (CMP) process. Accordingly, the sealing unit 400 may have a first surface 402 and a second surface 404 opposite to the first surface 402.

The first vertical conductive structure 310 may be a first conductive wire having the first end portion 312 bonded to the first chip pad 110 and a second end portion 314 opposite to the first end portion 312. The second vertical conductive structure 320 may be a second conductive wire having a first end portion 322 bonded to the second chip pad 210 and a second end portion 324 opposite to the first end portion 322. The second end portions 314 and 324 of the first and second vertical conductive structures 310 and 320 may be exposed from the first surface 402 of the sealing unit 400.

The first vertical conductive structure 310 may extend upward from the first chip pad 320 by a first height H1, and the second vertical conductive structure 320 may extend upward from the second chip pad 210 by a second height H2 greater than the first height H1. The first height H1 may be within a range of 10 μm to 50 μm, and the second height H2 may be within a range of 400 μm to 550 μm. The first and second heights H1 and H2 of the first and second vertical conductive structures 310 and 320 may be determined in consideration of the thicknesses of the first semiconductor chip 100 and the first adhesive film 120, the inductance of a signal path, the thickness of the entire package, etc.

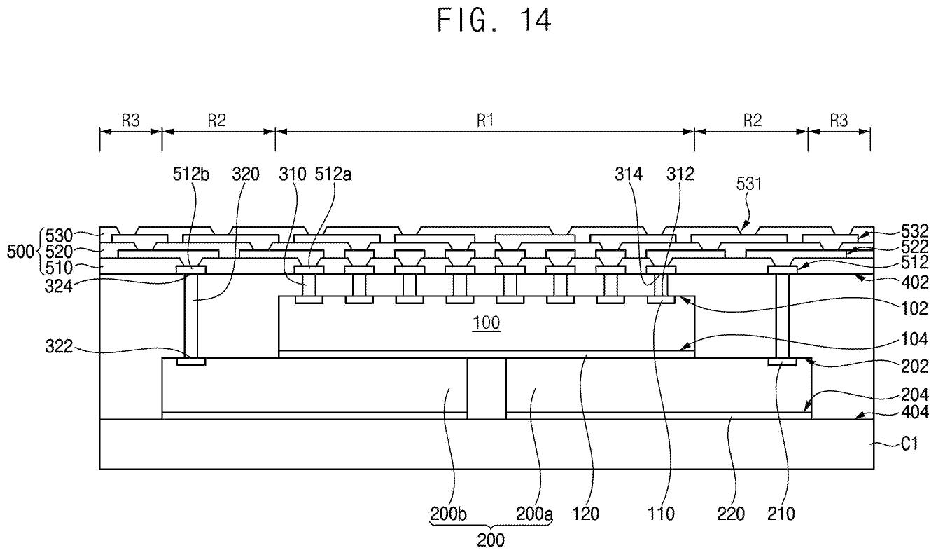

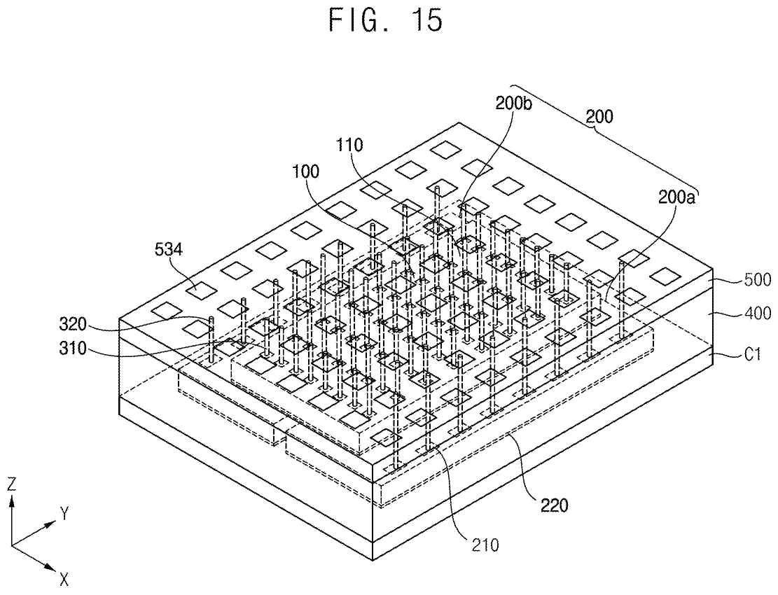

Referring to FIGS. 14 and 15, a redistribution wiring layer 500 having redistribution wirings 512, 522 and 532 electrically connected to the first and second vertical conductive structures 310 and 320 may be formed.

First, first redistribution wirings 512 electrically connected to the first and second vertical conductive structures 310 and 320 respectively may be formed on a first surface 402 of the sealing unit 400. The first redistribution wiring may be formed by forming a seed layer on the first surface 402 of the sealing unit 400, patterning the seed layer and performing an electro plating process.

For example, after an insulation layer is formed to cover the first surface 402 of the sealing unit 400, the insulation layer may be patterned to form openings that expose the second end portions 314 and 324 of the first and second vertical conductive structures 310 and 320. Then, after the seed layer is formed on a portion of the insulation layer and in the opening, the seed layer may be patterned and an electrolytic plating process may be performed to form the first redistribution wirings.

For example, the first redistribution wiring may include aluminum (Al), copper (Cu), tin (Sn), nickel (Ni), gold (Au), platinum (Pt) or an alloy thereof.

The first redistribution wirings 512 may include first uppermost redistribution wirings 512a that contact the first vertical conductive structures 310 respectively and second uppermost redistribution wirings 512b that contact the second vertical conductive structures 320 respectively.

Then, second and third redistribution wirings 522 and 532 electrically connected to the first redistribution wirings 512 may be sequentially formed.

For example, after a first insulating layer 510 is formed on the sealing unit 400, the first insulation layer 510 may be patterned to form openings that expose the first redistribution wirings 512. After a seed layer is formed on portions of the first redistribution wirings 512 and in the opening, the seed layer may be patterned and an electro plating process may be performed to form the second redistribution wirings 522. Accordingly, at least portions of the second redistribution wirings 522 may directly contact the first redistribution wirings 512 through the openings.

Similarly, after a second insulation layer 520 is formed on the first insulation layer 510, the second insulation layer 520 may be patterned to form openings that expose the second redistricting wirings 522. Then, the third redistribution wirings 532 may be formed on the second insulation layer 520 to directly contact the second redistribution wirings 522 through the openings.

Accordingly, the redistribution wiring layer 500 having the redistribution wirings 512, 522 and 532 stacked in at least two levels may be formed on the sealing unit 400.

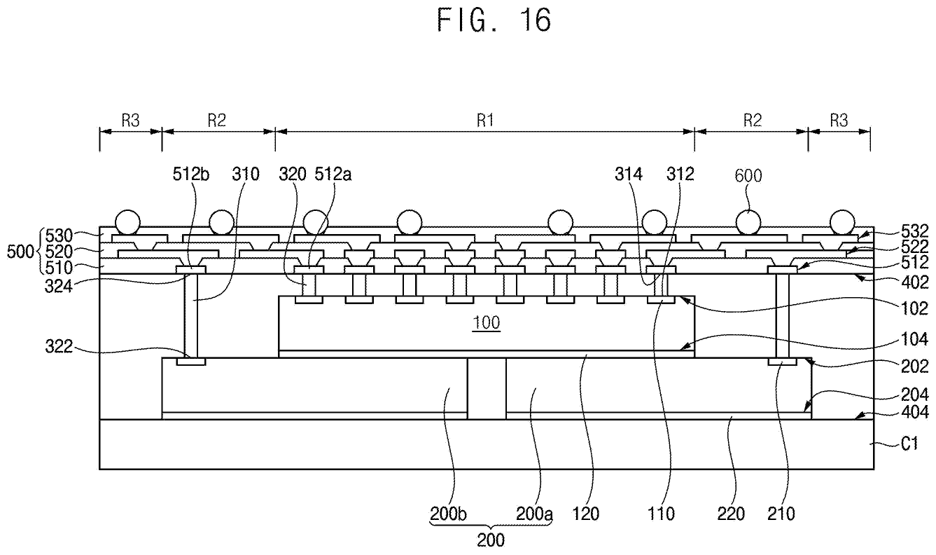

Then, openings 531 may be formed in the third insulation layer 530 to expose portions of the third redistribution wirings 532. The portion of the third redistribution wiring 532 exposed by the opening 531 may be used as a package pad 534 on which an external connection unit 600, as illustrated in FIG. 16, such as a solder ball, is disposed. In this case, the third insulating layer 530 may include a solder resist layer serving as a passivation layer.

In example embodiments, in a plan view, the redistribution wiring layer 500 may include a first region R1 overlapping the first semiconductor chip 100, a second region R2 surrounding the first region R1, and a third region R3 surrounding the second region R2. The second region R2 and the first region R1 inside the second region R1 may overlap the plurality of second semiconductor chips 200. The third region R3 may be a fan-out region outside the region where the first and second semiconductor chips are disposed, and some of the external connection units 600 may be arranged in the fan-out region.

Additionally, some of the first, second and third redistribution wirings 512, 522 and 532 may be used as channels for electrical connection between the first semiconductor chip 100 and the plurality of second semiconductor chips 200a and 200b. The second semiconductor chips 200a and 200b may be electrically connected to the first semiconductor chip 100 through one channel CH1 or two channels CH1 and CH2.

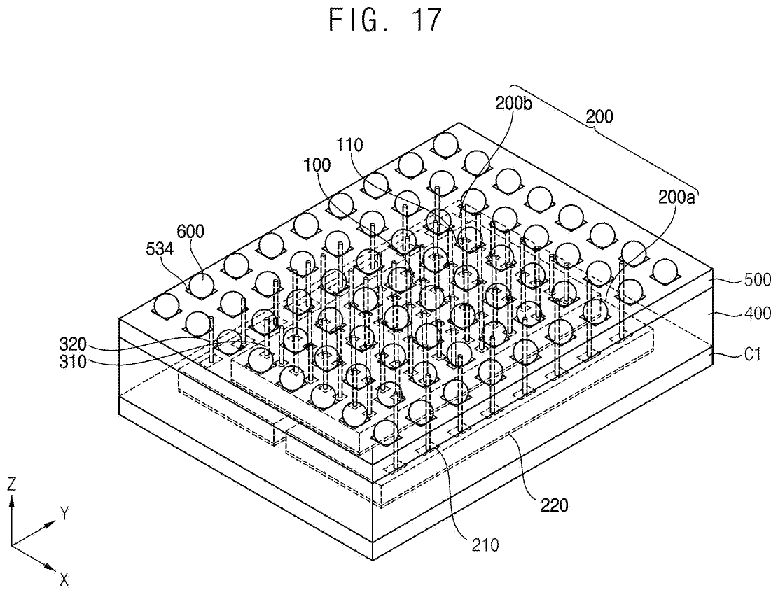

Referring to FIGS. 16 and 17, external connection terminals 600 electrically connected to the redistribution wirings may be formed on an outer surface of the redistribution wiring layer 500. For example, a solder ball may be formed as the external connection terminal on a portion of the third redistribution wiring 532. The outer connection terminals 600 may be formed on the package pads 534 on the outer surface of the redistribution wiring layer 500 by a solder ball attach process.

Then, the sealing unit 400 and the redistribution layer 500 may be cut to implement a semiconductor package as illustrated in FIG. 1, as an individual fan-out package.

In example embodiments, a second surface 404 of the sealing unit 400 may be exposed by removing the carrier substrate C1 from the sealing unit 400. At this time, the second adhesive film 220 may be exposed from the second surface 404 of the sealing unit 400.

In another embodiment, the second surface 404 of the sealing unit 400 may be polished. At this time, the second adhesive film 220 may be removed and the backside surfaces 204 of the second semiconductor chips 200a and 200b may be exposed from the second surface 404 of the sealing unit 400.

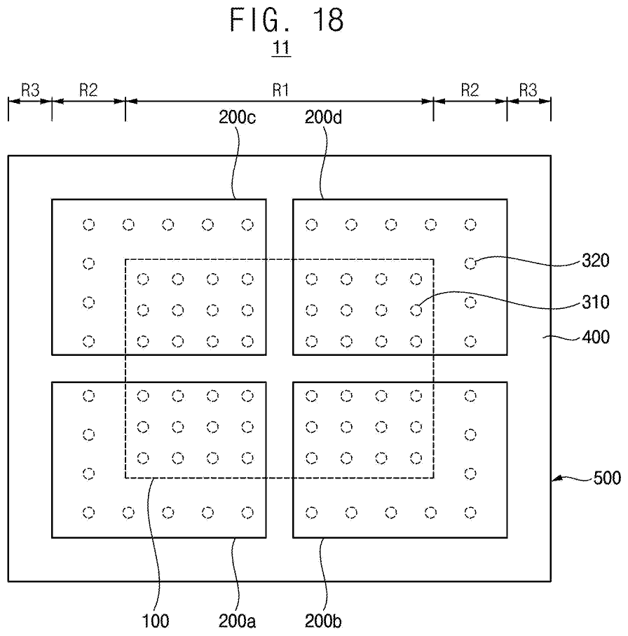

FIG. 18 is a plan view illustrating a semiconductor package in accordance with example embodiments. The semiconductor package may be substantially the same as or similar to the semiconductor package described with reference to FIGS. 1 and 2 except for additional second semiconductor chips. Thus, the same reference numerals will be used to refer to the same or like elements, and any further repetitive explanation concerning the above elements will be omitted.

Referring to FIG. 18, a semiconductor package 11 may include a first semiconductor chip 100 disposed on a redistribution wiring layer 500 via first conductive wires 310 and a plurality of second semiconductor chips 200 disposed on the redistribution wiring layer 500 and disposed on the first semiconductor chip 100.

In example embodiments, the second semiconductor chips 200a. 200b. 200c and 200d may be arranged on the first semiconductor chip 100 and are spaced apart from each other. The second semiconductor chips 200a, 200b, 200c, and 200d may be disposed at the same level on the first semiconductor chip 100. In some examples, the front surfaces of the second semiconductor chips 200a. 200b, 200c, and 200d are on the same horizontal plane and are not stacked on top of each other. In some examples, the first semiconductor 100 and the second semiconductor chips 200a, 200b. 200c, and 200d are positioned side by side on the first semiconductor chip 100, with a space between each other.

The number of the second semiconductor chips may not be limited thereto. For example, a number of six, eight, or ten second semiconductor chips may be stacked in one level on the first semiconductor chip 100.

Accordingly, since the plurality of second semiconductor chips 200a, 200b, 200c and 200d are arranged in one level on the first semiconductor chip 100, a fan-out package having a thin thickness may be provided.

Hereinafter, a method of manufacturing the semiconductor package in FIG. 18 will be explained.

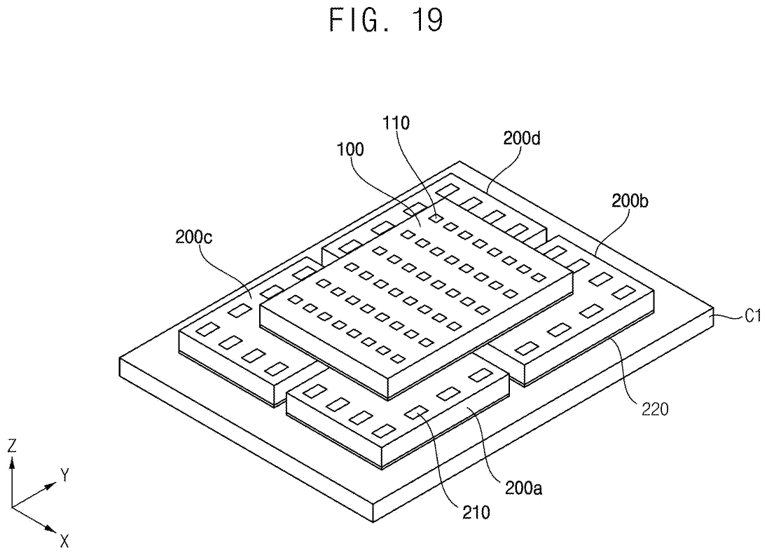

FIG. 19 is a perspective view illustrating a method of manufacturing a semiconductor package in accordance with example embodiments.

Referring to FIG. 19, processes the same as or similar to the processes described with reference to FIGS. 3 to 6 may be performed to arrange a plurality of second semiconductor chips 200 on a carrier substrate C1 and arrange a first semiconductor chip 100 on the plurality of second semiconductor chips 200.

In example embodiments, the second semiconductor chips 200a, 200b, 200c and 200d may be arranged on the first semiconductor chip 100 and are spaced apart from each other. In some examples, the second semiconductor chips 200a, 200b, 200c and 200d may be disposed at the same level and on the first semiconductor chip 100.

The first semiconductor chip 100 may be arranged on the plurality of second semiconductor chips 200 such that second chip pads 210 of the second semiconductor chips 200 are exposed by the first semiconductor chip 100. In a plan view, the first semiconductor chip 100 may be arranged in a rectangular support region provided by the second semiconductor chips 200a, 200b, 200c, and 200d. In some examples, the second chip pads 210 are positioned in a way that they are not covered or obstructed by the first semiconductor chip 100. In some cases, the second chip pads 210 are accessible and visible from the front surface of the first semiconductor chip 100. In some examples, the front surfaces of the second semiconductor chips 200a, 200b. 200c and 200d, where the second chip pads 210 are disposed, are positioned in a way that the second chip pads 210 are not hidden or covered by the first semiconductor chip 100 and are accessible and visible from the front surface of the first semiconductor chip 100. Accordingly, peripheral regions of the second semiconductor chips 200a, 200b, 200c, and 200d on which the second chip pads 210 are disposed may be exposed by the first semiconductor chip 100.

Then, processes the same as or similar to the process described with reference to FIGS. 7 to 17 may be performed to implement the semiconductor package as illustrated in FIG. 18.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that modifications are possible in the example embodiments without materially departing from the novel teachings and advantages of the present invention. Accordingly, the modifications are intended to be included within the scope of the present disclosure.

What is claimed is:

1. A semiconductor package, comprising:
a redistribution wiring layer having redistribution wirings stacked in at least two levels;
a first semiconductor chip arranged on the redistribution wiring layer, wherein first chip pads are formed on a front surface of the first semiconductor chip and the front surface of the first semiconductor chip faces the redistribution wiring layer;
a plurality of second semiconductor chips arranged on the first semiconductor chip, wherein second chip pads are formed on a front surface of the plurality of second semiconductor chips and the front surface of the plurality of second semiconductor chips faces the redistribution wiring layer, and wherein the second chip pads are exposed from the first semiconductor chip;
first conductive wires electrically connecting the first chip pads of the first semiconductor chip and the redistribution wirings of the redistribution wiring layer;
second conductive wires electrically connecting the second chip pads of the plurality of second semiconductor chips and the redistribution wirings of the redistribution wiring layer; and
a sealing unit disposed on the redistribution wiring layer and covering the first semiconductor chip, the plurality of second semiconductor chips, the first conductive wires, and the second conductive wires.

2. The semiconductor package of claim 1, wherein each of the plurality of second semiconductor chips includes an overhang portion that protrudes from a side of the first semiconductor chip, and
wherein the second chip pads are disposed on a lower surface of the overhang portion.

3. The semiconductor package of claim 1, wherein the plurality of second semiconductor chips are arranged at a same level on the first semiconductor chip and are spaced apart from each other.

4. The semiconductor package according to claim 1, wherein a backside surface of the first semiconductor chip is attached to the front surfaces of the plurality of second semiconductor chips with a first adhesive film.

5. The semiconductor package of claim 1, wherein the first conductive wire extends upward from a first uppermost redistribution wiring among the redistribution wirings to the first chip pad, and the second conductive wire extends upward from a second uppermost redistribution wiring among the redistribution wirings to the second chip pad.

6. The semiconductor package of claim 1, wherein the first conductive wire has a first height from the redistribution wiring layer, and the second conductive wire has a second height greater than the first height from the redistribution wiring layer.

7. The semiconductor package of claim 6, wherein the first height is 10 μm to 50 μm, and the second height is 400 μm to 550 μm.

8. The semiconductor package of claim 1, wherein second adhesive films are attached to backside surfaces of the plurality of second semiconductor chips.

9. The semiconductor package of claim 8, wherein the second adhesive films are exposed from an upper surface of the sealing unit.

10. The semiconductor package of claim 1, further comprising:
external connection units disposed on an outer surface of the redistribution wiring layer and electrically connected to the redistribution wirings,
wherein in a plan view, the redistribution wiring layer includes a fan-out region around the plurality of second semiconductor chips, and some of the external connection units are disposed in the fan-out region.

11. A semiconductor package, comprising:
a redistribution wiring layer including, in a plan view, a first region, a second region surrounding the first region, and a third region surrounding the second region, wherein first uppermost redistribution wirings are disposed in the first region and second uppermost redistribution wirings are disposed in the second region;
first conductive wires extending upward on the first uppermost redistribution wirings by a first height;
second conductive wires extending upward on the second uppermost redistribution wirings by a second height greater than the first height;
a first semiconductor chip disposed on the redistribution wiring layer via the first conductive wires;
a plurality of second semiconductor chips disposed on the redistribution wiring layer via the second conductive wires, wherein the plurality of second semiconductor chips are arranged on the first semiconductor chip; and
a sealing unit on the redistribution wiring layer and covering the first semiconductor chip, the plurality of second semiconductor chips, the first conductive wires, and the second conductive wires.

12. The semiconductor package of claim 11, wherein the first conductive wires electrically connect first chip pads disposed on the first semiconductor chip to the first redistribution wirings respectively, and the second conductive wires connect second chip pads disposed on the second semiconductor chip to the second redistribution wirings respectively.

13. The semiconductor package of claim 11, wherein each of the plurality of second semiconductor chips includes an overhang portion that protrudes from one side of the first semiconductor chip, and
wherein second chip pads disposed on the plurality of second semiconductor chip are disposed on the overhang portion.

14. The semiconductor package of claim 11, wherein the plurality of second semiconductor chips are disposed at a same level on the first semiconductor chip and are spaced apart from each other.

15. The semiconductor package of claim 11, wherein first chip pads are formed on a front surface of the first semiconductor chip and the front surface of the first semiconductor chip faces the redistribution wiring layer, and second chip pads are formed on a front surface of the plurality of second semiconductor chips and the front surface of the plurality of second semiconductor chips faces the redistribution wiring layer.

16. The semiconductor package of claim 15, wherein a backside surface of the first semiconductor chip is attached to front surfaces of the plurality of second semiconductor chips with a first adhesive film.

17. The semiconductor package of claim 15, wherein second adhesive films are attached to backside surfaces of the plurality of second semiconductor chips.

18. The semiconductor package of claim 11, wherein the first height is 10 μm to 50 μm, and the second height is 400 μm to 550 μm.

19. The semiconductor package of claim 11, further comprising:
external connection units disposed on an outer surface of the redistribution wiring layer,
wherein in the plan view, one or more of the external connection units are disposed in the third region.

20. A semiconductor package, comprising:
a plurality of second semiconductor chips, each of the plurality of second semiconductor chips having a front surface, wherein second chip pads are formed on the front surface and the plurality of second semiconductor chips are positioned at a same level and spaced apart from each other;
a first semiconductor chip arranged on the plurality of second semiconductor chips, wherein the second chip pads are exposed from the first semiconductor chip and first chip pads are formed on a front surface of the first semiconductor chip;
first conductive wires extending upwardly on the first chip pads by a first height;
second conductive wires extending upwardly on the second chip pads by a second height greater than the first height;
a sealing unit covering the plurality of second semiconductor chips, the first semiconductor chip, the first conductive wires, and the second conductive wires and exposing end portions of the first conductive wires and the second conductive wires; and
a redistribution wiring layer disposed on the sealing unit, the redistribution wiring layer having redistribution wirings electrically connected to the exposed end portions of the first conductive wires and the second conductive wires respectively.
